(19) United States
(12) Patent Application Publication
(10) Pub. No.: US 2008/0200031 A1
(43) Pub. Date: Aug. 21, 2008

(54) Method of fabricating gate electrode having polysilicon film and wiring metal film

(75) Inventors: Jang-hee Lee, Yongin-si (KR); Tae-ho Cha, Anyang-si (KR); Hae-sook Park, Seoul (KR); Gil-heyun Choi, Seoul (KR); Byung-hee Kim, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/007,999

(22) Filed: Jan. 18, 2008

(30) Foreign Application Priority Data
Jan. 18, 2007 (KR) 10-2007-0005815

(51) Int. Cl. H01L 21/44

(52) U.S. Cl. 438/684; 257/E21.476

(57) ABSTRACT

A method of forming a gate electrode of a semiconductor device according to example embodiments that may include forming a polysilicon film on a semiconductor substrate. An interface control layer may be formed on the polysilicon film by repeating a unit cycle a plurality of times. The unit cycle may include forming an interface metal film and nitriding an upper surface portion of the interface metal film to form an interface metal nitride film on an upper surface portion of the interface metal film. A wiring metal film may be formed on the interface control layer.

### PRIORITY STATEMENT

This application claims priority under 35 U.S.C. § 119 to Korean Patent Application No. 10-2007-0005815, filed on Jan. 18, 2007, in the Korean Intellectual Property Office, the entire contents of which are incorporated herein by reference.

### BACKGROUND

1. Field

Example embodiments are directed to a method of fabricating a gate electrode, and for example, a method of fabricating a gate electrode having a polysilicon film and a wiring metal film.

2. Description of the Related Art

As the width of signal lines decreases in connection with higher integration of semiconductor devices, there have been attempts to improve the conductivity of the signal lines. For example, a stacked structure of a polysilicon film and a wiring metal film may be developed, and the word line may act as a gate electrode of a transistor.

### SUMMARY

Unlike a polycide gate, which is a gate electrode with a stacked structure of a polysilicon film and a metal silicide film, a polymetal gate, which is a gate electrode with a stacked structure of a polysilicon film and a metal film, may include a multi-layered interface control layers between the polysilicon film and the metal film. The multi-layered interface control layers may have an ohmic contact film to lower a schottky barrier formed in an interface surface between the polysilicon film and the metal film, and may have a barrier film to reduce and/or prevent a heat-induced reaction between the polysilicon film and the metal film.

A process for forming a gate electrode having the stacked structure of the polysilicon film and the metal film may be complicated.

Example embodiments are directed to a simpler method of fabricating a polymetal gate that may involve a higher thermal stability and a lower interface resistance.

Example embodiments provide a method of forming a gate electrode of a semiconductor device that may include forming a polysilicon film on a semiconductor substrate, forming an interface control layer on the polysilicon film by repeating a unit cycle for plural times, the unit cycle including forming an interface metal film and nitriding an upper surface portion of the interface metal film to form an interface metal nitride film on an upper surface portion of the interface metal film, and forming a wiring metal film on the interface control layer.

Example embodiments also provide a method of forming a gate electrode of a semiconductor device that may include forming a polysilicon film on a semiconductor substrate, forming an interface control layer on the polysilicon film by repeating a unit cycle for plural times, where the unit cycle may include supplying metal precursor, supplying a reduction gas, and supplying a nitridation gas, and forming a wiring metal film on the interface control layer.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIGS. 1A through 1G are sectional views illustrating a method of forming a gate electrode of a semiconductor device according to example embodiments.

FIG. 2 is a timing diagram for forming an interface control layer according to example embodiments illustrated in FIGS. 1B through 1D.

FIG. 3 is a flow chart for forming the interface control layer according to example embodiments illustrated in FIGS. 1A through 1D.

FIGS. 4A and 4B are scanning electron microscopy (SEM) photographs with respect to specimens according to Fabrication Examples 1 and 2.

FIG. 5 is an SEM photograph with respect to a specimen according to an example embodiment.

FIGS. 6A and 6B are transmission electron microscope (TEM) photographs with respect to a specimen fabricated according to Fabrication Example 1.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

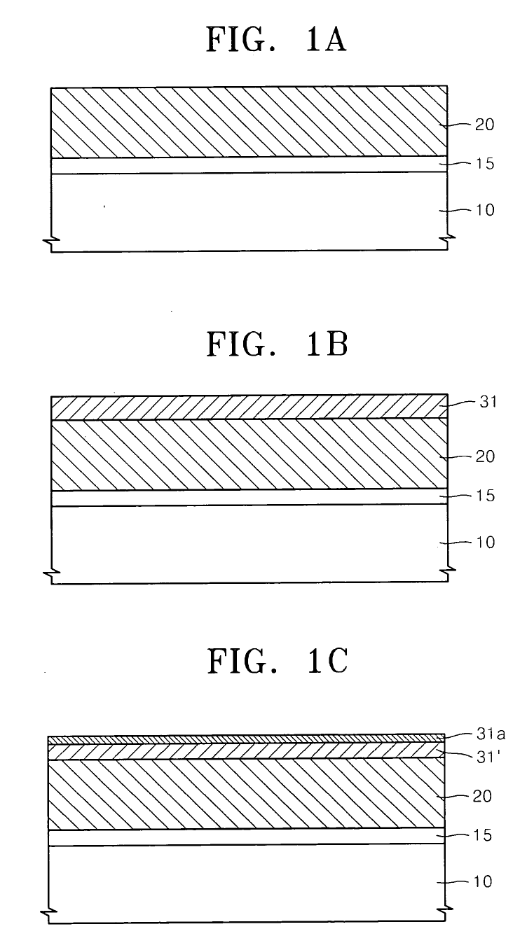

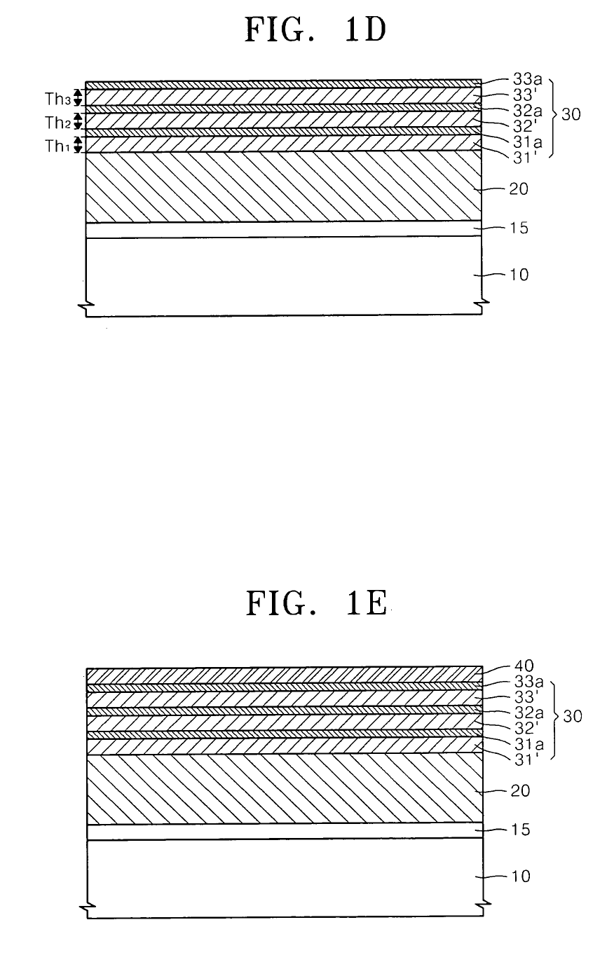

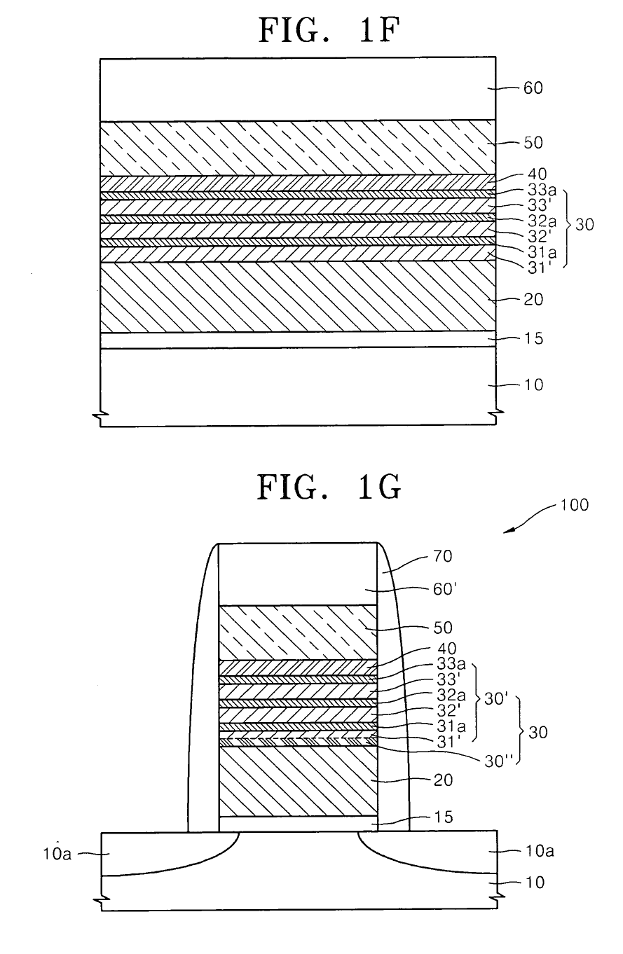

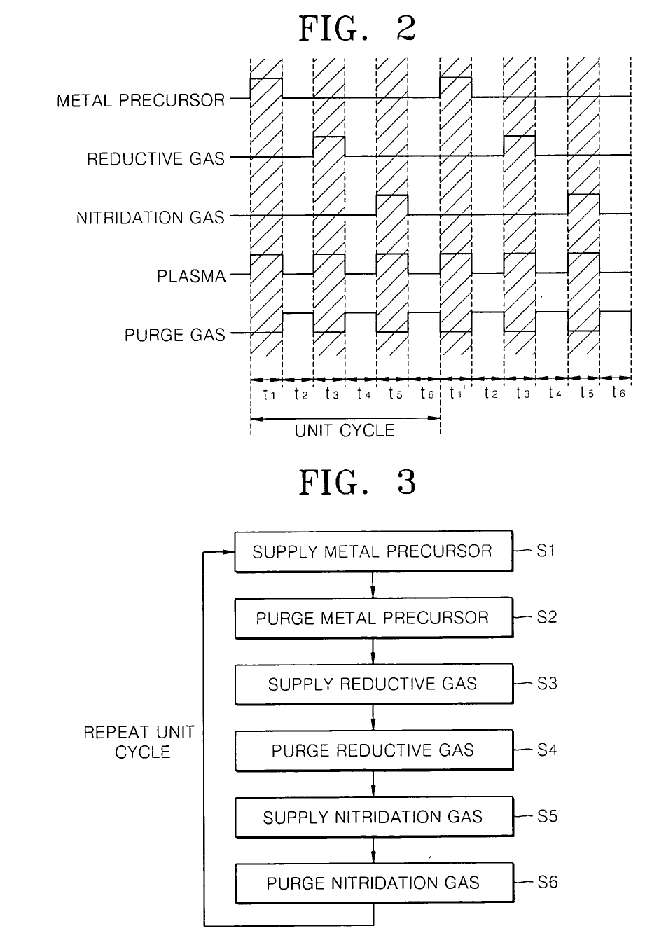

FIGS. 1A through 1G are sectional views illustrating example embodiments of a method of forming a gate electrode of a semiconductor device. FIG. 2 is a timing diagram for forming an interface control layer according to example embodiments illustrated in FIGS. 1B through 1D. FIG. 3 is a flow chart for forming the interface control layer according to example embodiments illustrated in FIGS. 1A through 1D.

Referring to FIG. 1A, a gate insulating film 15 may be formed on a semiconductor substrate 10. The gate insulating film 15 may be a silicon oxide film or other like film. A polysilicon film 20 may be formed on the gate insulating film 15. The polysilicon film 20 may be a conductive polysilicon film doped with n-type or p-type impurities or other like film.

Referring to FIGS. 1B, 2 and 3, the semiconductor substrate 10, upon which the polysilicon film 20 is formed, may be loaded within a reaction chamber. The semiconductor substrate 10 may be heated at a first temperature. Metal precursor may be supplied onto the polysilicon film 20 for a first duration time t₁, (S1 in FIG. 3). The metal precursor may react to the polysilicon film 20 and may stack on the polysilicon film 20. The metal precursor may be a metal halide or an organic metal compound or other like compound. For example, the metal precursor may be a titanium precursor, and more specifically TiCl₄, tetrakisdimethylaminotitanium (TDMAT), tetrakisdiethylaminotitanium (TDEAT) or tetrakisethylmethyltitanium (TEMAT).

Plasma may be generated by synchronizing to the duration time for supplying the metal precursor within the reaction chamber. The plasma may have a power of 5˜1000 W, for example. A bond between metal elements and halogen elements and/or a bond between metal elements and organic functional groups may be broken due to the plasma. Consequently, bonds between metal elements may be increased so that a multi-layered metal precursor layers can be stacked on the polysilicon film 20.

The supply of the metal precursor may be stopped, and a purge gas may be supplied into the reaction chamber for a second duration time t₂, so that unreacted metal precursor left within the reaction chamber may be purged (S2 in FIG. 3) and metal precursor may be left on the polysilicon film 20. The purge gas may be an inert gas, and for example, may be argon (Ar) or other like gas.

The supply of the purge gas may be stopped, and a reduction gas may be supplied into the reaction chamber for a third duration time t₃ (S3 in FIG. 3). The reduction gas, for example, may be hydrogen (H₂) or other like gas. The metal precursor stacked on the polysilicon film 20 may be reduced and may form a first interface metal film 31 on the polysilicon film 20. A bottom surface of the first interface metal film 31 may partially react to the polysilicon film 20 to form the metal suicide (not shown), and this reaction may occur simultaneously with the formation of the first interface metal film 31, for example.

In example embodiments where purging of the metal precursor (S2 in FIG. 3) is performed, the reaction between the metal precursor and the reduction gas during the supplying of the reduction gas (S3 in FIG. 3) may occur on the polysilicon film 20. Accordingly, by controlling the conditions of the supplying of the metal precursor (S1 in FIG. 3), such as a duration time or a flow quantity of the metal precursor, for example, a thickness of the metal precursor reacting onto the polysilicon film 20 may be controlled, so that a thickness of the first interface metal film 31 may be controlled.

Example embodiments provide that, if the metal precursor is TiCl₄ and the reduction gas is H₂, Reaction Equation 1 may occur, and the first interface metal film 31 may be a titanium film.

TiCl₄+2H₂(g)→Ti(s)+4HCl (g) [Reaction Equation 1]

Plasma may be generated by synchronizing the supply duration time of the reaction gas within the reaction chamber. The plasma may have a power of 50-1000 W, for example. The plasma may promote the reduction reaction, so that halogen elements existing in the first interface metal film 31 may be more efficiently removed.

The supply of the reduction gas may be stopped, and a purge gas may be supplied into the reaction chamber for a fourth duration time t₄ and may purge unreacted reduction gas and reaction byproducts (S4 in FIG. 3).

Referring to FIGS. 1C, 2 and 3, the supply of the purge gas may be stopped, and a nitridation gas may be supplied into the reaction chamber for a fifth duration time T₅ (S5 in FIG. 3). The nitridation gas may be nitrogen (N₂) or ammonium (NH₃) and an upper surface portion of the first interface metal film 31 may be nitrided. Thus, a first interface metal nitride film 31a may be formed within the upper portion of the first interface metal film 31, and the first interface metal film 31′ is left under the first interface metal nitride film 31a.

Example embodiments provide that, if the first interface metal film 31 is a titanium film, and the nitride gas is NH₃, Reaction Equation 2 may occur and the first interface metal nitride film 31a may be a titanium nitride film.

2Ti(s)+2NH₃(g)2TiN(s)+3H₂(g) [Reaction equation 2]

Plasma may be generated by synchronizing the duration time of supplying the nitridation gas within the reaction chamber. The plasma may have a power of 50-1000 W, for example, and may promote the nitridation reaction.

The supply of the nitridation gas may be stopped, and a purge gas may be supplied into the reaction chamber for a sixth duration time t₆ to purge unreacted nitridation gas and reaction byproducts (S6 in FIG. 3).

The supply of the metal precursor (S1 in FIG. 3), the supply of the reduction gas (S3 in FIG. 3), and the supply of the nitridation gas (S5 in FIG. 3) may constitute a unit cycle. Furthermore, the unit cycle may include the purge of the metal precursor (S2 in FIG. 3) between the supply of the metal precursor (S1) and the supply of the reduction gas (S3 in FIG. 3), and the purge of the reduction gas (S4 in FIG. 3) between the supply of the reduction gas (S3 in FIG. 3) and the supply of the nitridation gas (S5 in FIG. 3), and the purge of the nitridation gas (S6 in FIG. 3) after the supply of the nitridation gas (S5 in FIG. 3).

Referring to FIGS. 1D, 2 and 3, the unit cycle may be repeated a plurality of times, and for example, deposition cycling may be performed on the semiconductor substrate 10 where the interface metal nitride film 31a is formed. For example, when the unit cycle is repeated two additional times, a structure obtained by sequentially stacking a second interface metal film 32′, a second interface metal nitride film 32a, a third interface metal film 33′ and a third interface metal nitride film 33a may be formed on the first interface metal nitride film 31a. The stacked structure of the interface metal films 31′, 32′ and 33′ and the interface metal nitride films 31a, 32a and 33a may form an interface control layer 30. The semiconductor substrate may be maintained at the first temperature during the deposition cycling.

Example embodiments disclose a duration time t₁ of supplying metal precursor (S1 in FIG. 3) in a first cycle of unit deposition cycles may be longer than a duration time t₁′ of the supplying of the metal precursor (S1 in FIG. 3) in succeeding cycles. Consequently, a thickness Th₁ of the first interface metal film 31′ may be thicker than thicknesses Th₂ and Th₃ of the other interface metal films 32′, 33′. Moreover, all of the interface metal films 32′ and 33′ may be completely nitrided. The interface control layer 30 may be a structure obtained by sequentially stacking the first interface metal film 31′, the first interface metal nitride film 31a, the second interface metal nitride film 32a and the third interface metal nitride film 33a when, for example, the deposition cycle is repeated for three times in total.

Referring to FIG. 1E, a grain control layer 40 may be formed on the interface control layer 30 to increase dimensions of grains of a wiring metal film. The grain control layer 40 may be comprised of a material film selected from the group including tungsten silicide, molybdenum silicide, titanium silicide, tantalum silicide, hafnium silicide, cobalt silicide or other like films.

Referring to FIG. 1F, a wiring metal film 50 may be formed on the grain control layer 40. The wiring metal film 50 may be comprised of at least one material film selected from the group including tungsten (W), molybdenum (Mo), tantalum (Ta), cobalt (Co), titanium (Ti), aluminum (Al), copper (Cu), platinum (Pt), an alloy of these materials, or other like films.

A hardmask film 60 may be formed on the wiring metal film 50. The hardmask film 60 may be silicon nitride or other like film.

Referring to FIG. 1G, a photoresist pattern (not shown) may be formed on the hardmask film 60 and used as a mask for patterning the hardmask film 60 to form a hardmask pattern 60′. The wiring metal film 50, the grain control layer 40, the interface control layer 30 and the polysilicon film 20 may be etched using the hardmask patterns 60′ as a mask and a gate electrode 100 may be formed.

N-type or p-type impurities may be implanted into the semiconductor substrate 10 using the gate electrode 100 as a mask to form source/drain regions 10a. A spacer insulating film may be stacked on the semiconductor substrate 10 where the source/drain regions 10a are formed, and then may be anisotropically etched to form insulating spacers 70 on sidewalls of the stacked gate electrode 100.

An interlayer insulating film (not shown) may be stacked on the insulating spacers 70, and the semiconductor substrate 10 may be thermally treated at a thermally treating temperature. For example, at the thermally treating temperature, at least the lower surface portion of the first interface metal film 31′ may react to the polysilicon film 20 and form a metal silicide film 30″. Here, the metal silicide film 30″ may be formed in entire volume of the first interface metal film 31′. In this case, the metal silicide film 30″ contacts the first interface metal nitride film 31a.

Example embodiments are illustrated in the following fabrication examples.

### FABRICATION EXAMPLE 1

After a substrate with a polysilicon film stacked thereon was loaded to a reaction chamber, the substrate was heated at a temperature of 630° C. A unit cycle was repeated for three times to form a cyclically deposited Ti/TiN film. The unit cycle includes supplying TiCl₄ gas into the reaction chamber for 10.5 seconds, generating plasma by synchronizing to the supply of TiCl₄ gas, and then supplying Ar gas into the reaction chamber to purge the reaction chamber. The unit cycle includes supplying H₂ gas into the purged reaction chamber, generating plasma by synchronizing to the supply of H₂ gas, and then supplying Ar gas into the reaction chamber to purge the reaction chamber. The unit cycle includes supplying NH₃ gas into the purged reaction chamber for 10.5 seconds, generating plasma by synchronizing to the NH₃ gas and then supplying Ar gas into the reaction chamber to purge the reaction chamber. A tungsten film with a thickness of 300 Å was deposited on the resultant structure using chemical vapor deposition (CVD), and the substrate was thermally treated at a temperature of 850° C. for 30 minutes.

### FABRICATION EXAMPLE 2

A specimen was prepared according to the fabrication example 1 except that TiCl₄ gas is supplied for 30 seconds in the first of the three unit cycles.

### COMPARATIVE EXAMPLE

A polysilicon film was stacked on a substrate, and a titanium (Ti) film to a thickness of 60 Å was deposited on the polysilicon film using physical vapor deposition (PVD). A titanium nitride (TiN) film of a thickness of 100 Å was deposited on the titanium film using PVD, and a tungsten (W) film was deposited to a thickness of 300 Å on the TiN film using chemical vapor deposition (CVD). The substrate was thermally treated at a temperature of 850° C. for 30 minutes.

The Table 1 displays process conditions of the Fabrication Examples 1 and 2.

TABLE 1

| | First Cycle | | Second Cycle | | Third Cycle | |
|---|---|---|---|---|---|---|
| | Supply of | Supply of | Supply of | Supply of | Supply of | Supply of |
| Step | TiCl₄ gas | NH₃ gas | TiCl₄ gas | NH₃ gas | TiCl₄ gas | NH₃ gas |
| Fabrication | 10.5 | 10.5 | 10.5 | 10.5 | 10.5 | 10.5 |
| Example 1 | seconds | seconds | seconds | seconds | seconds | seconds |
| Fabrication | 30 | 10.5 | 10.5 | 10.5 | 10.5 | 10.5 |
| Example 2 | seconds | seconds | seconds | seconds | seconds | seconds |

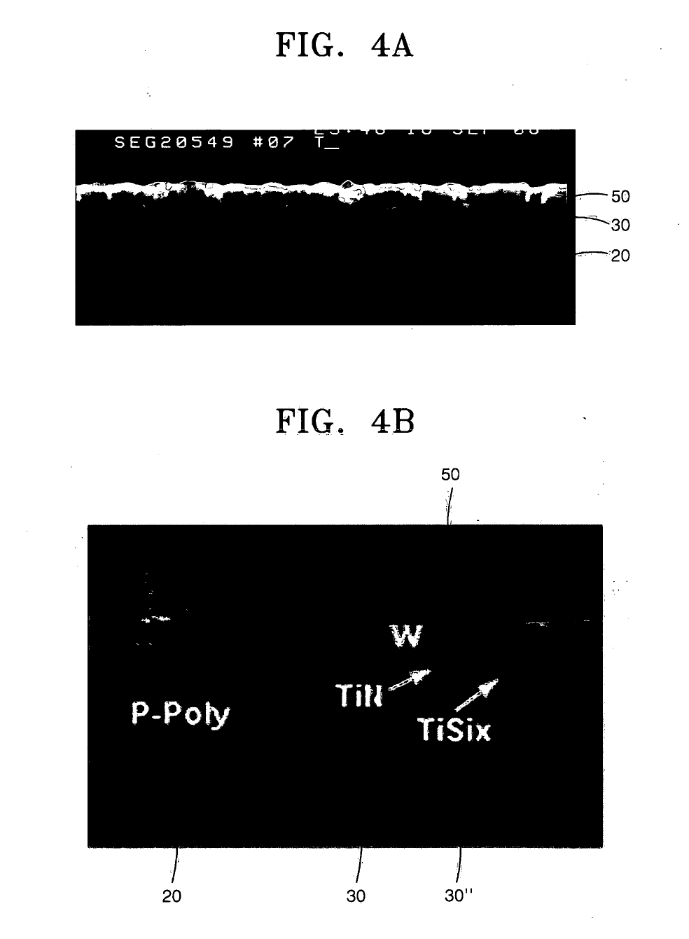

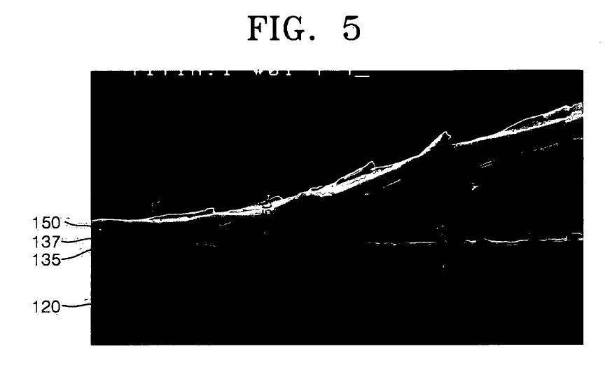

FIGS. 4A and 4B are scanning electron microscopy (SEM) photographs of specimens according to the Fabrication Examples 1 and 2. FIG. 5 is an SEM photograph with respect to the specimen of the Comparative Example.

In the specimens shown in FIGS. 4A and 4B, a polysilicon film 20, a cyclically deposited Ti/TiN film 30 and a tungsten film 50 were sequentially stacked. In FIG. 4A, a titanium silicide film was scarcely checked in the lower portion of the cycling deposited Ti/TiN film 30. However, a titanium silicide film 30″ with a thickness of about 60 Å was formed on the lower surface portion of the cyclically deposited Ti/TiN film 30 in FIG. 4B. Therefore, when a supply time of the TiCl₄ metal precursor of the first cycle was increased, a thickness of the titanium silicide film was increased.

In the specimens shown in FIGS. 4A and 4B, the polysilicon film 20 and the cyclicly deposited Ti/TiN film 30 are never lifted off from each other. In FIG. 5, where a polysilicon film 120, a PVD Ti film 135, a PVD TiN film 137, and a tungsten film 150 are sequentially stacked, there is lift-off on an interface of the polysilicon film 120 and the PVD Ti film 135 dissimilar to that of FIGS. 4A and 4B.

The unit cycle forming the interface metal film and forming the interface nitrided metal film by nitriding at least the upper surface portion of the interface metal film may be repeated in fabrication examples. Thus, the thickness of the interface metal film contacting the polysilicon film may be decreased, and agglomeration of the excessive metal silicide during the thermal treatment may be reduced and/or prevented. The lift-off between the polysilicon film and the cyclically deposited the interface control layer, may be reduced and/or prevented.

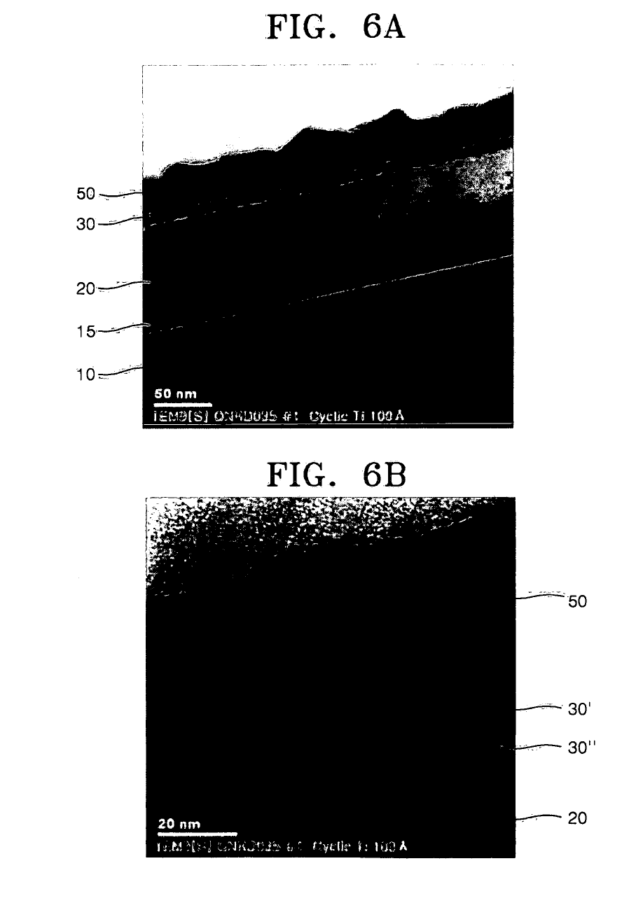

FIGS. 6A and 6B are transmission electron microscope (TEM) photographs of a specimen fabricated according to Fabrication Example 1. FIG. 6B is a partially enlarged view of FIG. 6A.

Referring to FIGS. 6A and 6B, a titanium silicide film 30″ is formed on the lower surface portion of the Ti/TiN film 30. Thus, the polysilicon film 20 and the cyclically deposited Ti/TiN film 30 form an ohmic contact.

According to example embodiments, a unit cycle that includes forming a thin interface metal film and forming an interface nitrided metal film by nitriding at least upper surface portion of the interface metal film may be repeated. Therefore, a thickness of the interface metal film contacting the polysilicon film may be decreased to reduce and/or agglomeration of excessive metal silicide when performing thermal treatment. Thus, the lower surface of the interface metal film may react to the polysilicon film to form a metal silicide film and attain an ohmic contact between the polysilicon film and the interface control layer. Accordingly, the interface control layer may simultaneously act as an ohmic contact layer and a barrier film.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

1. A method of forming a gate electrode of a semiconductor device comprising:
forming a polysilicon film on a semiconductor substrate;
forming an interface control layer on the polysilicon film by repeating a unit cycle a plurality of times, the unit cycle including forming an interface metal film and nitriding an upper surface portion of the interface metal film to form an interface metal nitride film on an upper surface portion of the interface metal film; and
forming a wiring metal film on the interface control layer.

2. The method of claim 1, wherein the forming of the interface metal film includes supplying metal precursor onto the polysilicon film, and supplying a reduction gas.

3. The method of claim 2, wherein plasma is generated when supplying the metal precursor.

4. The method of claim 2, further includes purging the metal precursor between the supplying of the metal precursor and the supplying of the reduction gas.

5. The method of claim 2, wherein the metal precursor is metal halides.

6. The method of claim 6, wherein the metal precursor is TiCl₄.

7. The method of claim 2, wherein the reduction gas is hydrogen.

8. The method of claim 1, wherein the forming of the interface metal nitride film includes supplying a nitridation gas.

9. The method of claim 2, wherein the forming of the interface metal nitride film includes supplying a nitridation gas after supplying the reduction gas.

10. The method of claim 9, wherein plasma is generated when supplying the nitridation gas.

11. The method of claim 10, further including purging a reduction gas between supplying the reduction gas and supplying the nitridation gas.

12. The method of claim 10, further including purging the nitridation gas after the nitridation gas is supplied.

13. The method of claim 9, wherein the nitridation gas is nitrogen or ammonia.

14. The method of claim 1, further including thermally treating the substrate.

15. The method of claim 1, further including forming a grain control layer on the interface control layer before forming the wiring metal film.

16. A method of forming a gate electrode of a semiconductor device comprising:
forming a polysilicon film on a semiconductor substrate;
forming an interface control layer on the polysilicon film by repeating a unit cycle a plurality of times, the unit cycle including supplying metal precursor, supplying a reduction gas, and supplying a nitridation gas; and
forming a wiring metal film on the interface control layer.

17. The method of claim 18, further including purging between the supplying of the metal precursor and the supplying of the reduction gas, purging between the supplying of the reduction gas and the supplying the nitridation gas, and purging after supplying the nitridation gas.

18. The method of claim 18, wherein plasma is generated when supplying the metal precursor, and when supplying the reduction gas, and when supplying the nitridation gas.

19. The method of claim 18, wherein the metal precursor is TiCl₄, the reduction gas is hydrogen, and the nitridation gas is ammonia.

20. The method of claim 18, further including thermally treating the substrate.
